(19) United States
(12) Patent Application Publication
(10) Pub. No.: US 2024/0140256 A1
(43) Pub. Date: May 2, 2024

(54) ESTIMATION OF REMAINING BATTERY CHARGE TIME IN STATIONARY ELECTRIC VEHICLES

(71) Applicant: GM GLOBAL TECHNOLOGY OPERATIONS LLC, Detroit, MI (US)

(72) Inventors: Amirthamshan Murugesapillai, Pickering (CA); Orson S. Wang, Northville, MI (US); Tommy Sloan, Novi, MI (US); Orlando Ward-Santos, Ann Arbor, MI (US)

(73) Assignee: GM GLOBAL TECHNOLOGY OPERATIONS LLC, Detroit, MI (US)

(21) Appl. No.: 17/979,151

(22) Filed: Nov. 2, 2022

(51) Int. Cl. B60L 58/12; B60L 1/00; B60L 50/60; B60L 58/24; G01R 31/382; H01M 10/48; H01M 10/625; H02J 7/00

(52) U.S. Cl. CPC B60L 58/12; B60L 1/003; B60L 50/60; B60L 58/24; G01R 31/382; H01M 10/482; H01M 10/486; H01M 10/625; H02J 7/0048; B60L 2240/70; H01M 2220/20

(57) ABSTRACT

A method of determining remaining charge time in a rechargeable energy storage system (RESS) of an electric vehicle (EV) having an auxiliary system includes determining available amount of energy in the RESS when the EV is stationary. The method also includes determining amounts of RESS energy and time required to achieve auxiliary system steady state operation and remaining RESS energy to maintain auxiliary system steady state operation after the steady state is achieved. The method additionally includes determining time left for maintaining the steady state operation based on the amount of remaining RESS energy and RESS power consumption required for maintaining the steady state operation. Furthermore, the method includes determining the remaining RESS charge time based on time to achieve and amount of time left to maintain the steady state operation and triggering a signal indicative of the remaining charge time.

### INTRODUCTION

The present disclosure generally relates to estimation of remaining battery charge time in stationary electric vehicles.

An electrical energy storage or battery system or array may include a plurality of battery cells in relatively close proximity to one another. A plurality of battery cells may be assembled into a battery stack or module, and a plurality of battery modules may be assembled into a battery pack. In large battery packs, an individual pack may also be split into separate battery sub-packs, each including an array of battery modules. Batteries may be broadly classified into primary and secondary batteries.

Primary batteries, also referred to as disposable batteries, are intended to be used until depleted of charge, after which they are simply replaced with new batteries. Secondary batteries, more commonly referred to as rechargeable batteries, employ specific high-energy chemistries permitting such batteries to be repeatedly recharged and reused, therefore offering economic, environmental, and ease-of-use benefits compared to disposable batteries. Rechargeable batteries may be used to power such diverse items as toys, consumer electronics, and rotary electric machines, such as electric motors-generators or traction motors for electric propulsion of motor vehicles. Battery cells may be actively depleted of charge during operation of the powered item or through self-discharge during storage.

In an electric vehicle powertrain employing the above-described rotary electric machine, energy is drawn from the cells of the battery system, i.e., the battery cells are actively discharging, whenever the electric powertrain is functioning in a drive or propulsion mode. Additionally, the battery cells continue to actively discharge when the vehicle is stationary with the powertrain dormant, but accessory and/or auxiliary systems, such as heating, ventilation, and air conditioning (HVAC), infotainment, or battery conditioning, continue to operate.

### SUMMARY

A method of determining charge time remaining in a multi-cell rechargeable energy storage system (RESS) employed in an electric vehicle (EV) having a traction motor for propulsion thereof and an auxiliary system, each powered by the RESS. The method includes determining, via an electronic controller, when the EV is stationary and the traction motor is not operating. The method also includes determining, via the electronic controller, an available amount of energy in the RESS. The method additionally includes determining, via the electronic controller, an amount of energy required from the RESS to achieve a predetermined steady state operation of the auxiliary system when the EV is stationary and the traction motor is not operating. The method also includes determining, via the electronic controller, an amount of time to achieve the predetermined steady state operation of the auxiliary system when the EV is stationary.

The method additionally includes determining, via the electronic controller, an amount of energy remaining in the RESS and RESS power consumption required to maintain the predetermined steady state operation of the auxiliary system after the predetermined steady state operation is achieved. The method also includes determining, via the electronic controller, an amount of time available or left to maintain the predetermined steady state operation of the auxiliary system as a function of the determined amount of energy remaining and RESS power consumption required to maintain the predetermined steady state operation. The method additionally includes determining, via the electronic controller, the charge time remaining in the RESS as a function of the determined amount of time to achieve the predetermined steady state operation of the auxiliary system and the determined amount of time available to maintain the predetermined steady state operation of the auxiliary system. Furthermore, the method includes triggering, via the electronic controller, a first sensory signal indicative of the determined charge time remaining in the RESS.

Determining the amount of energy required from the RESS to each of achieve and maintain the predetermined steady state operation of the auxiliary system may include determining ambient temperature relative to the stationary EV.

Determining the amount of energy required from the RESS to each of achieve and maintain the predetermined steady state operation of the auxiliary system may additionally include determining temperature of the RESS.

The auxiliary system may be a conditioning system configured to regulate temperature of the RESS.

Determining the amount of energy required from the RESS to each of achieve and maintain the predetermined steady state operation of the auxiliary system may further include determining temperature inside a vehicle passenger cabin.

The auxiliary system may be a heating, ventilation, and air conditioning (HVAC) system configured to control climate inside the vehicle passenger cabin.

The method of determining charge time remaining in the RESS may additionally include recalculating or updating, e.g., in response to passage of time or a change in ambient conditions, the determined remaining battery charge time, via the electronic controller. In such an embodiment, the method may additionally include triggering, via the electronic controller, a second sensory signal indicative of the recalculated remaining battery charge time.

The method of determining charge time remaining in the RESS may additionally include triggering, via the electronic controller, a third sensory signal indicative of the determined remaining battery charge time having reached a preset remaining battery charge time.

The amount of energy required from the RESS to each of achieve and maintain the predetermined steady state operation of the auxiliary system may be determined as a function of the determined available amount of energy in the RESS using respective calibration tables accessed by or programmed into the electronic controller.

The method of determining charge time remaining in the RESS may further include wirelessly communicating the first sensory signal to a personal communication device arranged externally to the EV, such as a mobile telephone, a laptop, or a personal computer.

An electric motor vehicle having the RESS, the traction motor and the auxiliary system powered by the RESS, and the electronic controller configured to determine charge time remaining in the RESS when the traction motor is not powered but the auxiliary system is powered, is also disclosed.

The above features and advantages, and other features and advantages of the present disclosure, will be readily apparent from the following detailed description of the embodiment(s) and best mode(s) for carrying out the described disclosure when taken in connection with the accompanying drawings and appended claims.

### BRIEF DESCRIPTION OF THE DRAWINGS

FIG. 1 is a schematic top view of an embodiment of an electric vehicle (EV) employing a powertrain with a traction motor configured to propel the vehicle and a multi-cell rechargeable energy storage system (RESS) configured to supply the electrical energy to the traction motor and auxiliary systems configured to operate when the vehicle is stationary and the traction motor is off, and an electronic controller operatively connected to each of the RESS, traction motor, and auxiliary systems according to the disclosure.

FIG. 2 illustrates representative calibration tables used by the electronic controller to determine amounts of RESS electrical energy, time, and power consumption required to achieve and maintain a predetermined steady state operation of the auxiliary systems based on ambient temperature, according to the disclosure.

FIG. 3 illustrates a method of determining charge time remaining in RESS for operating auxiliary system(s) in a stationary EV shown in FIGS. 1 and 2 when the EV traction motor is off, according to the disclosure.

### DETAILED DESCRIPTION

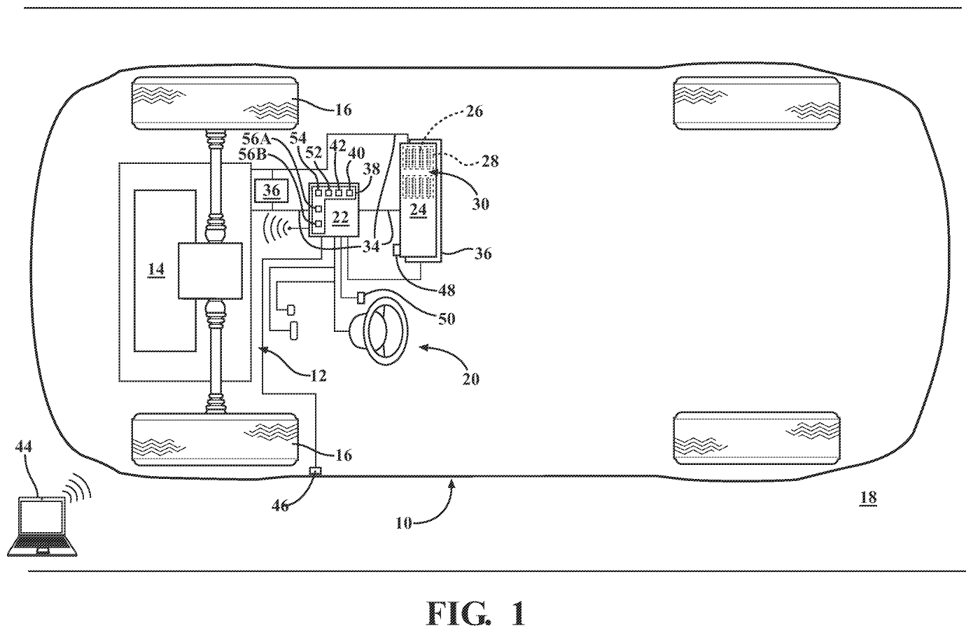

Referring to FIG. 1, an electric vehicle (or EV) 10 having a powertrain 12 is depicted. The vehicle 10 may include, but not be limited to, a commercial vehicle, industrial vehicle, passenger vehicle, aircraft, watercraft, train, or the like. It is also contemplated that the vehicle 10 may be a mobile platform, such as an airplane, all-terrain vehicle (ATV), boat, personal movement apparatus, robot, and the like to accomplish the purposes of this disclosure. The powertrain 12 includes a power-source 14 configured to generate a power-source torque T (shown in FIG. 1) for propulsion of the vehicle 10 via driven wheels 16 relative to a road surface 18. The power-source 14 is depicted as an electric traction motor-generator. The vehicle 10 also includes a vehicle interior or passenger cabin 20.

The vehicle 10 additionally includes a programmable electronic controller 22 and a multi-cell rechargeable energy storage system (RESS) 24. A general structure of the RESS 24 is schematically shown in FIG. 1. As shown, a plurality of battery cells 26 may be initially combined into cell groups 28, where the individual cells may be arranged in parallel. The cell groups 28 may be subsequently organized into battery modules 30, where the individual cell groups are arranged, i.e., connected, in series. A single module 30 is shown in FIG. 1, but the RESS 24 may have as many such modules as desired. A plurality of modules 30 may then be arranged in individual battery sub-packs (not shown). Operation of the powertrain 12 and the RESS 24 may be generally regulated by the electronic controller 22. The RESS 24 may be operatively connected to the power-source 14, the electronic controller 22, as well as other vehicle systems via a high-voltage BUS 34 (shown in FIG. 1).

The RESS 24 is configured to generate and store electrical energy through heat-producing electro-chemical reactions, and in the vehicle 10 may be used to supply the electrical energy by being electrically connected to the power-source 14. In certain vehicle modes, the power-source 14 may operate in generator mode, thereby recharging the RESS 24. The electronic controller 22 may be programmed to control the powertrain 12 and the RESS 24 to generate a predetermined amount of power-source torque T, and various other vehicle systems. The electronic controller 22 may include a central processing unit (CPU) that regulates various functions on the vehicle 10 or be configured as a powertrain control module (PCM) configured to control the powertrain 12. In either of the above configurations, the electronic controller 22 includes a processor and tangible, non-transitory memory, which includes instructions for operation of the powertrain 12 and the RESS 24 programmed therein.

The memory of the electronic controller 22 may be an appropriate recordable medium that participates in providing computer-readable data or process instructions. Such a recordable medium may take many forms, including but not limited to non-volatile media and volatile media. Non-volatile media for the electronic controller 22 may include, for example, optical or magnetic disks and other persistent memory. Volatile media may include, for example, dynamic random-access memory (DRAM), which may constitute a main memory. Such instructions may be transmitted by one or more transmission medium, including coaxial cables, copper wire and fiber optics, including the wires that comprise a system bus coupled to a processor of a computer, or via a wireless connection. Memory of the electronic controller 22 may also include a flexible disk, hard disk, magnetic tape, another magnetic medium, a CD-ROM, DVD, another optical medium, etc.

The electronic controller 22 may be configured or equipped with other required computer hardware, such as a high-speed clock, requisite Analog-to-Digital (A/D) and/or Digital-to-Analog (D/A) circuitry, input/output circuitry and devices (I/O), as well as appropriate signal conditioning and/or buffer circuitry. Algorithms required by the electronic controller 22 or accessible thereby may be stored in the memory and automatically executed to provide the required functionality of the powertrain 12 and the RESS 24. The electronic controller 22 is also configured to monitor the RESS 24 and process data, such as via the subject algorithms, for the plurality of battery cells 26. The electronic controller 22 may be in wireless communication with external device(s), such as a mobile telephone, a laptop, or a personal computer (PC) accessible by an owner or operator of the EV 10.

The vehicle 10 further includes one or more auxiliary power-consuming systems 36. The auxiliary systems 36 are electrically powered by the RESS 24. An embodiment of the auxiliary system 36 may be an RESS conditioning system configured to regulate temperature of the RESS 24 within a predetermined or desired range, which may depend on the particular chemistry of the subject RESS, or to a predetermined target temperature value. For example, the electronic controller 22 may be configured to control flow and/or temperature of a coolant through the RESS 24, such as by circulating the coolant through a coolant plate arranged adjacent the battery cells 26 (not shown). Controlled flow and/or temperature of the coolant is intended to either remove thermal energy from the RESS 24 when the battery temperature exceeds the predetermined range or add thermal energy to the RESS when the temperature of battery cells falls below the subject range. The electronic controller 22 may also be configured to regulate temperature of the RESS 24 by removing thermal energy from the battery cells 26 via controlling a speed of a cooling fan (not shown), which may be arranged proximate to or inside an individual battery module 30.

Another embodiment of the auxiliary system 36 may be a heating, ventilation, and air conditioning (HVAC) system configured to control climate inside the vehicle passenger cabin 20. The HVAC system may be configured to operate when the EV 10 is being propelled by the traction motor 14 or when the EV remains stationary with the traction motor off. The HVAC system may be left on when the EV 10 is otherwise shut off, for example when the EV's operator steps away from the vehicle for a limited duration but leaves temperature sensitive merchandise or a pet in the vehicle. The electronic controller 22 is also configured to monitor operation of the auxiliary systems 36. The auxiliary systems 36 may be active, both during regular vehicle 10 operation, i.e., when the traction motor 14 is generating torque and propelling the vehicle, and when the traction motor is off. In other words, the auxiliary systems 36 may be powered by the RESS 24 while the vehicle 10 is stationary and even when the vehicle is not occupied by the driver or vehicle passengers.

The electronic controller 22 is programmed with an algorithm 38 for determining, in real-time, according to a method described below, total charge time remaining t_{R} in the RESS 24. Using the algorithm 38, the electronic controller 22 is configured, i.e., programmed, to ascertain when the EV 10 is stationary and is not being powered by the traction motor 14. The electronic controller 22 is also configured to determine the RESS 24 state of charge (SOC) and therewith determine a total available amount of energy E_{T} in the RESS while the EV 10 is stationary. A stationary EV 10 may be in a parked state, such as having been vacated by the vehicle operator, or trapped in gridlock traffic with the operator remaining inside. SOC is generally the level of charge of an electric battery relative to its capacity. The units of SOC are percentage points (0%=empty; 100%=full). An alternative form of the same measure is the depth of discharge (DOD), the inverse of SOC (100%=empty; 0%=full). SOC is normally used when discussing the current state of a battery in use, while DOD is most often seen when discussing the lifetime of the battery after repeated use. The total available amount of energy E_{T} in the RESS 24 is a function of the RESS initial capacity and its SOC.

Either concurrently or proximately in time with the determination of the total available amount of energy E_{T} in the RESS 24, the electronic controller 22 is configured to also monitor operation of the traction motor 14 to determine when the traction motor is not operating. In other words, the electronic controller 22 determines when the RESS 24 is not supplying the electrical power to the traction motor 14 and the traction motor is neither generating torque nor recharging the RESS. The electronic controller 22 is additionally configured to determine an amount of energy E_{A} required to be drawn from the RESS 24 over time (in a transient mode) to initially achieve a predetermined steady state operation 40 of the auxiliary system(s) 36. The electronic controller 22 is also configured to determine an amount of time t_{A} required to achieve the predetermined steady state operation 40 of the auxiliary system(s) 36.

The electronic controller 22 is further configured to determine an amount of energy remaining E_{M} in the RESS 24 and RESS power consumption P_{M} required to maintain the predetermined steady state operation 40 of the auxiliary system(s) 36 after the predetermined steady state operation has been achieved. The RESS power consumption P_{M} required to maintain the predetermined steady state operation 40 of the auxiliary system(s) 36 may be determined using a respective look-up calibration table (to be described in detail below) programmed into the electronic controller 22. Alternatively, the RESS power consumption P_{M} may be determined based on instantaneous current and voltage, i.e., a measured power output of the RESS 24. In a further embodiment, the RESS power consumption P_{M} may be determined using periodic weather forecasting accessed by the electronic controller 22.

The electronic controller 22 is also configured to determine an amount of time t_{M} available or left to maintain the predetermined steady state operation 40 of the auxiliary system(s) 36 as a function of the determined amount of energy remaining E_{M} and RESS power consumption P_{M} required to maintain the predetermined steady state operation. The electronic controller 22 is also configured to determine the charge time t_{R} remaining in the RESS 24 as a function of the determined amount of time t_{A} to achieve the predetermined steady state operation 40 of the auxiliary system(s) 36 and the determined amount of time t_{M} left to maintain the predetermined steady state operation. The electronic controller 22 is further configured to trigger a first sensory signal 42 indicative of the determined charge time t_{R} remaining in the RESS 24 when the EV 10 is stationary.

In the embodiment where both the RESS conditioning and HVAC auxiliary systems 36 continue to operate in the stationary EV 10, the relationships between the above variables may be defined by the following expressions:
1) The amount of time t_{A} to achieve the predetermined steady state operation 40 for both auxiliary systems 36 is the maximum amount of either the time to reach predetermined steady state (target) HVAC temperature or the time to reach predetermined steady state RESS temperature
2) The total transient energy E_{A} required to achieve the predetermined steady state operation 40 of both the RESS conditioning and HVAC auxiliary systems 36 is the sum of (a) and (b) below:
   (a) Energy required to achieve cabin target temperature may be based on a corresponding HVAC calibration table (to be described below), which is generally equal to the product of power consumption P_{A_cabin} and overall transient time t_{A} to achieve the predetermined steady state temperature of the subject auxiliary system. Alternatively, the energy required to achieve cabin target temperature may be expressed as instantaneous power consumption to achieve a predetermined steady state cabin temperature integrated over the overall transient time t_{A}.
   (b) Energy required to achieve RESS target temperature may be based on a corresponding RESS calibration table (to be described below), which is generally equal to the product of power consumption to achieve RESS conditioning target PA_RESS and overall transient time t_{A} to achieve the predetermined steady state temperature of the subject auxiliary system. Alternatively, the energy required to achieve RESS target temperature may be expressed as instantaneous power consumption to achieve a predetermined steady state RES S temperature integrated over transient time t_{A}.
3) The total estimated steady state power consumption P_{M} to maintain target temperature is equal to the sum of amounts of power required to maintain the steady state condition of each auxiliary system (power to maintain RESS target temperature plus power to maintain cabin target temperature).
4) The energy E_{M} available for maintaining steady state operation 40 of both the RESS conditioning and HVAC auxiliary systems 36 is equal to RESS remaining energy minus total required transient energy E_{A}.
5) The estimated steady state time t_{M} is equal to energy available for steady state E_{M} divided by total estimated steady state RESS power consumption P_{M}.
6) The estimated time available t_{R} is equal to the sum of estimated overall transient time to and estimated steady state time t_{M}.

The electronic controller 22 may communicate the determined remaining battery charge time t_{R}, the first sensory signal 42, wirelessly to a personal communication device 44 arranged externally to the EV 10, such as a laptop (shown in FIG. 1), a PC (not shown), or a mobile telephone (not shown). The electronic controller 22 may be additionally configured to determine or acquire ambient temperature T_{ambient} relative to the stationary EV, such as via a temperature sensor 46 arranged externally with respect to the passenger cabin 20. The electronic controller 22 may then use the determined ambient temperature T_{ambient} to determine the amount of energy E_{A} required to achieve the predetermined steady state operation 40 and the amount of RESS power consumption P_{M} required to maintain the predetermined steady state operation of the auxiliary system(s) 36. As part of the algorithm 38, the electronic controller 22 may also be configured to determine or acquire temperature T_{RESS} of the RESS 24, such as via a temperature sensor 48 arranged proximate to or internal to the RESS. The electronic controller 22 may then use the determined temperature T_{RESS} to determine the amount of energy E_{A} to achieve and the amount of RESS conditioning portion of power consumption P_{M} required to maintain the predetermined steady state operation 40 of the auxiliary system(s) 36.

The electronic controller 22 may be additionally configured to determine or acquire temperature T_{cabin} inside the passenger cabin 20, such as via a temperature sensor 50 arranged within the passenger cabin. The electronic controller 22 may then use the determined temperature T_{cabin} to determine the amounts of energy E_{A} and the RESS power consumption P_{M} required from the RESS 24 to each of achieve and maintain the predetermined steady state operation 40 of the auxiliary system(s) 36. The electronic controller 22 may be further configured to recalculate or update the determined remaining battery charge time t_{R}, e.g., in response to passage of time or change in ambient conditions since the first sensory signal 42 was triggered, to generate a recalculated remaining battery charge time t_{RR}. The electronic controller 22 may then trigger an updated or second sensory signal 52 indicative of the recalculated remaining battery charge time t_{RR}. The electronic controller 22 may be additionally configured to trigger a third sensory signal 54 indicative of the determined remaining battery charge time t_{R} having reached a preset remaining battery charge time tp. Each of the second and third sensory signals 52, 54 may be wirelessly communicated by the electronic controller 22 to the personal communication device 44.

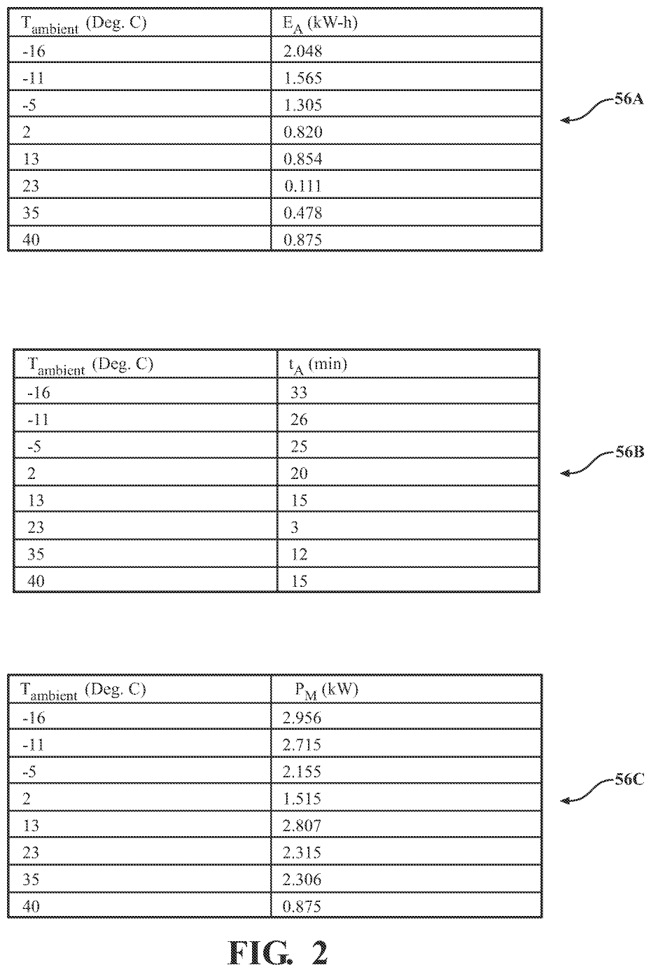

The electronic controller 22 may be configured to determine the amounts of energy E_{A} and RESS 24 power consumption P_{M} required from the RESS 24 to each of achieve and maintain the predetermined steady state operation 40 of the auxiliary system(s) 36, generally as a function of the determined total available amount of energy E_{T}, via respective accessed calibration tables 56A, 56B, and 56C (shown in a representative fashion in FIG. 2). Specifically, the subject calibration tables may be programmed into the electronic controller 22, wherein the calibration table(s) 56A provides energy E_{A} to be drawn from the RESS 24 versus ambient temperature T_{ambient} for achieving steady state condition of a particular auxiliary system 36 (e.g., the cabin 20, the RESS 24, etc); the calibration table(s) 56B provides time to required to achieve predetermined steady state temperature of each auxiliary system 36 (the RESS 24, the cabin 20, etc.) versus ambient temperature T_{ambient}; and the calibration table(s) 56C providing RESS 24 power consumption P_{M} required to maintain the predetermined target temperature of the RESS 24 versus ambient temperature T_{ambient}.

Overall, the determination of the available remaining charge time t_{R} in the RESS 24 is intended to provide the EV operator with an estimate of the amount of time the EV may be left unattended with operating auxiliary functions and without risking complete depletion of the RESS charge. Additionally, the EV 10 may update its operator of changes to the initial estimate and permit the operator to modify plans for returning to and/or charging of the vehicle. The algorithm 38 programmed into the electronic controller 22 takes into account traction motor off operation of such auxiliary systems 36 as the RESS conditioning and vehicle HVAC, permitting a more accurate prediction of available remaining charge time t_{R} in the RESS 24.

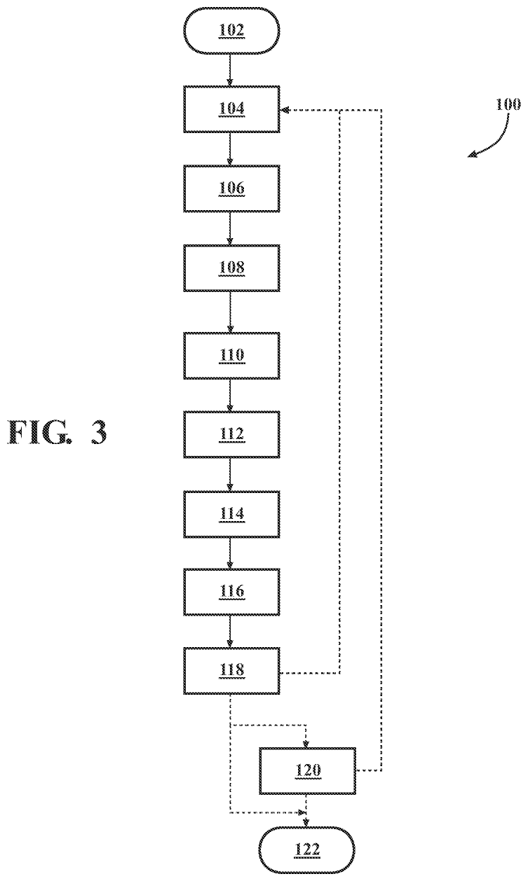

A method 100 of determining or predicting the charge time t_{R} remaining in the RESS 24 for operating auxiliary system(s) 36 is shown in FIG. 3 and described below with reference to the structure and correlation tables shown respectively in FIGS. 1 and 2. Method 100 commences in frame 102 with monitoring operation of the EV 10, the RESS 24, and the auxiliary system(s) 36. After frame 102, the method proceeds to frame 104. In frame 104, the method includes determining, via the electronic controller 22, if and when the EV 10 is stationary and the traction motor 14 is not operating. Following frame 104, the method advances to frame 106. In frame 106, the method includes determining, via the electronic controller 22, total available amount of energy E_{T} in the RESS 24. From frame 106, the method moves on to frame 108.

In frame 108 the method includes determining, via the electronic controller 22, the amount of energy E_{A} required from the RESS 24 to achieve the predetermined steady state operation 40 of the auxiliary system when the EV 10 is stationary and the traction motor 14 is not operating. In frame 108, the method may include determining ambient temperature T_{ambient} relative to the stationary EV 10 to determine the amount of energy E_{A} to achieve, and subsequently, the amount of power P_{M} to maintain, the steady state operation 40. Additionally, to determine the amount of energy E_{A} (and subsequently P_{M}), the method may include determining the current temperature of the RESS 24 (T_{RESS}). In frame 108, the method may further include determining temperature T_{cabin} inside the vehicle passenger cabin 20 to determine the amount of energy E_{A} and subsequently P_{M}. As described above with respect to FIGS. 1 and 2, the amounts of energy E_{A} and RESS power consumption P_{M} may be determined as a function of the determined total available amount of energy E_{T} or the SOC in the RESS 24 and ambient temperature T_{ambient} using respective calibration tables 56A, 56B, 56C accessed by the electronic controller 22. After frame 108, the method advances to frame 110.

In frame 110, the method includes determining, via the electronic controller 22, the amount of time to needed to achieve the predetermined steady state operation of the auxiliary system(s) 36. Following frame 110, the method advances to frame 112. In frame 112, the method includes determining, via the electronic controller 22, the amount of energy remaining E_{M} in the RESS 24 to maintain the predetermined steady state operation 40 of the auxiliary system(s) 36 after the predetermined steady state operation has been achieved. After frame 112, the method proceeds to frame 114, where the method includes determining, via the electronic controller 22, the amount of time t_{M} left to maintain the predetermined steady state operation 40 of the auxiliary system(s) 36. As described above with respect to FIGS. 1 and 2, the amount of time t_{M} left to maintain the predetermined steady state operation 40 is determined as a function of the determined amount of energy remaining E_{M} and the RESS power consumption P_{M} required to maintain the predetermined steady state operation. From frame 114, the method moves on to frame 116.

In frame 116, the method includes determining, via the electronic controller 22, the charge time t_{R} remaining in the RESS 24. As described above, the amount of time t_{R} remaining in the RESS 24 is determined as a function of the determined amount of time t_{A} to achieve the predetermined steady state operation 40 of the auxiliary system(s) 36 and the determined amount of time t_{M} left to maintain the predetermined steady state operation. Following frame 116, the method advances to frame 118. In frame 118, the method includes triggering, via the electronic controller 22, the first sensory signal 42 indicative of the determined charge time t_{R} remaining in the RESS 24 when the EV 10 is stationary. In frame 118, the method may include wirelessly communicating, via the electronic controller 22, the determined remaining battery charge time t_{R} to a user or operator of the EV 10 using a personal communication device, such as a mobile telephone, a laptop, or a PC. After frame 118, the method may proceed to frame 120.

In frame 120, the method includes recalculating to update the determined remaining battery charge time t_{R}, e.g., in response to passage of time or change in ambient conditions), via the electronic controller 22. In frame 120 the method may also include triggering the second sensory signal 52 indicative of the remaining battery charge time t_{RR} recalculated after the triggered first sensory signal 42. Furthermore, in frame 120 the method may include triggering the third sensory signal 54 indicative of the determined remaining battery charge time t_{R} having reached the preset remaining battery charge time tp. In frame 120, the method may include wirelessly communicating, via the electronic controller 22, the sensory signal 52 or 54 to the personal communication device 44 of the user or operator of the EV 10. Following either of the frames 118 or 120, the method may loop back to frame 104 for another assessment whether the EV 10 is stationary and the traction motor 14 is off. Alternatively, the method may conclude in frame 122.

The detailed description and the drawings or figures are supportive and descriptive of the disclosure, but the scope of the disclosure is defined solely by the claims. While some of the best modes and other embodiments for carrying out the claimed disclosure have been described in detail, various alternative designs and embodiments exist for practicing the disclosure defined in the appended claims. Furthermore, the embodiments shown in the drawings or the characteristics of various embodiments mentioned in the present description are not necessarily to be understood as embodiments independent of each other. Rather, it is possible that each of the characteristics described in one of the examples of an embodiment may be combined with one or a plurality of other desired characteristics from other embodiments, resulting in other embodiments not described in words or by reference to the drawings. Accordingly, such other embodiments fall within the framework of the scope of the appended claims.

What is claimed is:

1. A method of determining charge time remaining in a multi-cell rechargeable energy storage system (RESS) employed in an electric vehicle (EV) having a traction motor for propulsion thereof and an auxiliary system, each powered by the RESS, the method comprising:
determining, via an electronic controller, when the EV is stationary;
determining, via the electronic controller, an available amount of energy in the RES S;
determining, via the electronic controller, an amount of energy required from the RESS to achieve a predetermined steady state operation of the auxiliary system when the EV is stationary;
determining, via the electronic controller, an amount of time to achieve the predetermined steady state operation of the auxiliary system;
determining, via the electronic controller, an amount of energy remaining in the RESS and RESS power consumption required to maintain the predetermined steady state operation of the auxiliary system after the predetermined steady state operation is achieved;
determining, via the electronic controller, an amount of time available to maintain the predetermined steady state operation of the auxiliary system as a function of the determined amount of energy remaining in the RESS and RESS power consumption required to maintain the predetermined steady state operation;
determining, via the electronic controller, the charge time remaining in the RESS as a function of the determined amount of time to achieve the predetermined steady state operation of the auxiliary system and the determined amount of time available to maintain the predetermined steady state operation; and
triggering, via the electronic controller, a first sensory signal indicative of the determined charge time remaining in the RESS when the EV is stationary.

2. The method of determining charge time remaining in the RESS according to claim 1, wherein determining the amount of energy required from the RESS to each of achieve and maintain the predetermined steady state operation of the auxiliary system includes determining ambient temperature relative to the stationary EV.

3. The method of determining charge time remaining in the RES S according to claim 2, wherein determining the amount of energy required from the RESS to each of achieve and maintain the predetermined steady state operation of the auxiliary system further includes determining temperature of the RESS.

4. The method of determining charge time remaining in the RESS according to claim 3, wherein the auxiliary system is an RESS conditioning system configured to regulate temperature of the RESS.

5. The method of determining charge time remaining in the RES S according to claim 2, wherein determining the amount of energy required from the RESS to each of achieve and maintain the predetermined steady state operation of the auxiliary system further includes determining temperature inside a passenger cabin of the EV.

6. The method of determining charge time remaining in the RESS according to claim 5, wherein the auxiliary system is a heating, ventilation, and air conditioning (HVAC) system configured to control climate inside the passenger cabin of the EV.

7. The method of determining charge time remaining in the RESS according to claim 1, further comprising recalculating, via the electronic controller, after the triggered first sensory signal, the determined remaining battery charge time and triggering a second sensory signal indicative of the recalculated remaining battery charge time.

8. The method of determining charge time remaining in the RESS according to claim 1, further comprising triggering, via the electronic controller, a third sensory signal indicative of the determined remaining battery charge time having reached a preset remaining battery charge time.

9. The method of determining charge time remaining in the RESS according to claim 1, wherein the amount of energy required from the RESS to each of achieve and maintain the predetermined steady state operation of the auxiliary system is determined as a function of the determined available amount of energy in the RESS using respective calibration tables accessed by the electronic controller.

10. The method of determining charge time remaining in the RESS according to claim 1, further comprising wirelessly communicating the first sensory signal to a personal communication device arranged externally to the EV.

11. An electric vehicle (EV) comprising:
a multi-cell rechargeable energy storage system (RESS) having a plurality of battery cells;
a traction motor configured to be powered by the RESS and generate propulsion of the EV;
an auxiliary system powered by the RESS; and
an electronic controller operatively connected to each of the RESS, the traction motor, and the auxiliary system and configured to:
determine when the EV is stationary;
determine an available amount of energy in the RESS;
determine an amount of energy required from the RESS to achieve a predetermined steady state operation of the auxiliary system when the EV is stationary;
determine an amount of time to achieve the predetermined steady state operation of the auxiliary system;
determine an amount of energy remaining in the RESS and RESS power consumption required to maintain the predetermined steady state operation of the auxiliary system after the predetermined steady state operation is achieved;
determine an amount of time available to maintain the predetermined steady state operation of the auxiliary system as a function of the determined amount of energy remaining and RESS power consumption required to maintain the predetermined steady state operation;
determine a charge time remaining in the RESS as a function of the determined amount of time to achieve the predetermined steady state operation of the auxiliary system and the determined amount of time available to maintain the predetermined steady state operation; and
trigger a first sensory signal indicative of the determined charge time remaining in the RESS when the EV is stationary.

12. The EV according to claim 11, wherein the electronic controller is additionally configured to determine ambient temperature relative to the stationary EV and use the determined ambient temperature to determine the amount of energy required from the RESS to each of achieve and maintain the predetermined steady state operation of the auxiliary system.

13. The EV according to claim 12, wherein the electronic controller is additionally configured to determine temperature of the RESS and use the determined temperature of the RESS to determine the amount of energy required from the RESS to each of achieve and maintain the predetermined steady state operation of the auxiliary system.

14. The EV according to claim 13, wherein the auxiliary system is an RESS conditioning system configured to regulate temperature of the RES S.

15. The EV according to claim 12, further comprising a vehicle passenger cabin, wherein the electronic controller is additionally configured to determine temperature inside the passenger cabin and use the determined temperature inside the passenger cabin to determine the amount of energy required from the RESS to each of achieve and maintain the predetermined steady state operation of the auxiliary system, and wherein the auxiliary system is a heating, ventilation, and air conditioning (HVAC) system configured to control climate inside the vehicle passenger cabin.

16. The EV according to claim 11, wherein the electronic controller is additionally configured, after the triggered first sensory signal, to recalculate the determined remaining battery charge time and trigger a second sensory signal indicative of the recalculated remaining battery charge time.

17. The EV according to claim 11, wherein the electronic controller is additionally configured to trigger a third sensory signal indicative of the determined remaining battery charge time having reached a preset remaining battery charge time.

18. The EV according to claim 11, wherein the electronic controller is configured to determine the amount of energy required from the RESS to each of achieve and maintain the predetermined steady state operation of the auxiliary system as a function of the determined available amount of energy in the RESS via respective accessed calibration tables.

19. The EV according to claim 11, wherein the electronic controller is configured to wirelessly communicate the first sensory signal to a personal communication device arranged externally to the EV.

20. A method of determining charge time remaining in a multi-cell rechargeable energy storage system (RESS) employed in an electric vehicle (EV) having a traction motor for propulsion thereof and an auxiliary system, each powered by the RESS, the method comprising:
determining, via an electronic controller, when the EV is stationary and the traction motor is not operating;
determining, via the electronic controller, an available amount of energy in the RES S;
determining, via the electronic controller, an amount of energy required from the RESS to achieve a predetermined steady state operation of the auxiliary system when the EV is stationary and the traction motor is not operating;
determining, via the electronic controller, an amount of time to achieve the predetermined steady state operation of the auxiliary system;
determining, via the electronic controller, an amount of energy remaining in the RESS and RESS power consumption required to maintain the predetermined steady state operation of the auxiliary system after the predetermined steady state operation is achieved;
determining, via the electronic controller, an amount of time available to maintain the predetermined steady state operation of the auxiliary system as a function of the determined amount of energy remaining in the RESS and RESS power consumption required to maintain the predetermined steady state operation;
determining, via the electronic controller, the charge time remaining in the RESS as a function of the determined amount of time to achieve the predetermined steady state operation of the auxiliary system and the determined amount of time to maintain the predetermined steady state operation;
triggering, via the electronic controller, a first sensory signal indicative of the determined charge time remaining in the RESS when the EV is stationary; and
wirelessly communicating, via the electronic controller, the first sensory signal to a personal communication device arranged externally to the EV.
